(19) United States
(12) Patent Application Publication
(10) Pub. No.: US 2016/0106000 A1
(43) Pub. Date: Apr. 14, 2016

(54) LOW PROFILE HEAT SINK

(71) Applicant: Panasonic Automotive Systems Company of America, Division of Panasonic Corporation of North America, Peachtree City, GA (US)

(72) Inventor: GERALD ANTHONY TANG-KONG, NEWNAN, GA (US)

(73) Assignee: Panasonic Automotive Systems Company of America, Division of Panasonic Corporation of North America

(21) Appl. No.: 14/881,338

(22) Filed: Oct. 13, 2015

Related U.S. Application Data
(60) Provisional application No. 62/063,021, filed on Oct. 13, 2014.

(51) Int. Cl. H05K 7/20

(52) U.S. Cl. CPC H05K 7/20409

(57) ABSTRACT

A heat sink for an electronic component includes a base having a width. The base has a greater thickness at a middle portion along the width than at opposite end portions along the width. A plurality of elongate fins project from an upper surface of the base and extend in directions perpendicular to the upper surface.

### CROSS-REFERENCE TO RELATED APPLICATIONS

This application claims the benefit of U.S. Provisional Application No. 62/063,021, filed on Oct. 13, 2014, which the disclosure of which is hereby incorporated by reference in its entirety for all purposes.

### BACKGROUND OF THE INVENTION

1. Field of the Invention.

The present invention relates to a heat sink, and, more particularly, to a heat sink for dissipating heat from a microprocessor or similar device.

2. Description of the Related Art.

Heat sinks are known to physically engage and carry heat away from electronic components that otherwise may be damaged by the heat. The heat sink typically is made of aluminum and has a base with a surface that contacts the electronic component. The heat sink also typically has a series of fins extending from the base in a direction away from the electronic component. The fins provide a large surface area within a limited three-dimensional space to thereby increase the rate of convection of heat from the heat sink to the air.

### SUMMARY OF THE INVENTION

The invention may provide a heat sink for use under natural convection conditions and with surface mount devices. The outer side of the base of the heat sink has a convex shape, and the base is thicker at the middle of the base than at the ends of the base. Thus, the heat sink has a higher capacity to carry away heat from the middle of the printed circuit board, where the board is hottest. The fins may fan out away from the base of the heat sink due to the convex external surface of the base. That is, the distance between adjacent fins increases along the heights of the fins. The increased distance between adjacent fins may enable the fins to have greater thicknesses. Thus, the heat sink may have higher heat capacity as compared to the equivalent envelope of a traditional heat sink.

The heat sink may include fins in the middle of the heat sink of greater thickness than the fins on the ends of the heat sink. The thickness of the fins in the middle of the heat sink may be tapered such that the fins become progressively thinner towards the distal ends thereof.

The heat sink may include trenches of semi-circular cross section on the upper surface of the base between the fins. Each trench may be disposed between a respective pair of the fins. The trenches increase the surface area on the upper surface of the base thereby increasing the heat dissipating capacity of the heat sink.

The heat sink may enable the design of an external audio amplifier that is less than 40 millimeters in overall height and dissipates 15 W of heat (Class I) version).

The invention comprises, in one form thereof, a heat sink for an electronic component, including a base having a width. The base has a greater thickness at a middle portion along the width than at opposite end portions along the width. A plurality of elongate fins project from an upper surface of the base and extend in directions perpendicular to the upper surface.

The invention comprises, in another form thereof, a heat sink for an electronic component, including a base having a convexly shaped surface. A plurality of elongate fins project from the surface of the base and extend in directions perpendicular to the surface.

The invention comprises, in another form thereof, a heat sink for an electronic component, including a base having a surface. A plurality of substantially parallel channels are disposed in the surface. A plurality of elongate fins project from the surface of the base and extend in directions perpendicular to the surface and parallel to the channels. Each fin is disposed between two adjacent channels.

An advantage of the present invention is that it may provide increased heat dissipation when compared to traditional heat sinks both under natural convection conditions and under forced air conditions.

Another advantage of the present invention is that the entire surface of the heat sink may be utilized for heat dissipation. Thus, a smaller package is enabled with shorter fins.

### BRIEF DESCRIPTION OF THE DRAWINGS

The above-mentioned and other features and objects of this invention, and the manner of attaining them, will become more apparent and the invention itself will be better understood by reference to the following description of embodiments of the invention taken in conjunction with the accompanying drawings, wherein:

FIG. 1a is a top perspective view of one embodiment of a heat sink of the present invention.

FIG. 1b is another top perspective view of the heat sink of FIG. 1a.

FIG. 2a is a front view of the heat sink of FIG. 1a.

FIG. 2b is another front view of the heat sink of FIG. 1a.

FIG. 2c is an enlarged view of the circular area A in FIG. 2b.

FIG. 3a is a bottom perspective view of the heat sink of FIG. 1a.

FIG. 3b is another bottom perspective view of the heat sink of FIG. 1a.

FIG. 4a is a bottom view of the heat sink of FIG. 1a.

FIG. 4b is another bottom view of the heat sink of FIG. 1a.

FIG. 5 is a side view of the heat sink of FIG. 1a.

FIG. 6 is a top perspective view of the heat sink of FIG. 1a attached to an electronic component.

FIG. 7a is a top perspective view of another embodiment of a heat sink of the present invention.

FIG. 7b is another top perspective view of the heat sink of FIG. 7a.

FIG. 8a is a front view of the heat sink of FIG. 7a.

FIG. 8b is another front view of the heat sink of FIG. 7a.

FIG. 9a is a bottom perspective view of the heat sink of FIG. 7a.

FIG. 9b is another bottom perspective view of the heat sink of FIG. 7a.

FIG. 10a is a bottom view of the heat sink of FIG. 7a.

FIG. 10b is another bottom view of the heat sink of FIG. 7a.

FIG. 11 is a side view of the heat sink of FIG. 7a.

### DETAILED DESCRIPTION

Glossary

Fins—standing ridges on an ordinarily hot object, such as a heat sink, a radiator, etc., intended to increase heat transfer to the surrounding air by exposing a large surface area.

Channels—long, narrow cuts or indentations in a surface.

The embodiments hereinafter disclosed are not intended to be exhaustive or limit the invention to the precise forms disclosed in the following description. Rather the embodiments are chosen and described so that others skilled in the art may utilize its teachings.

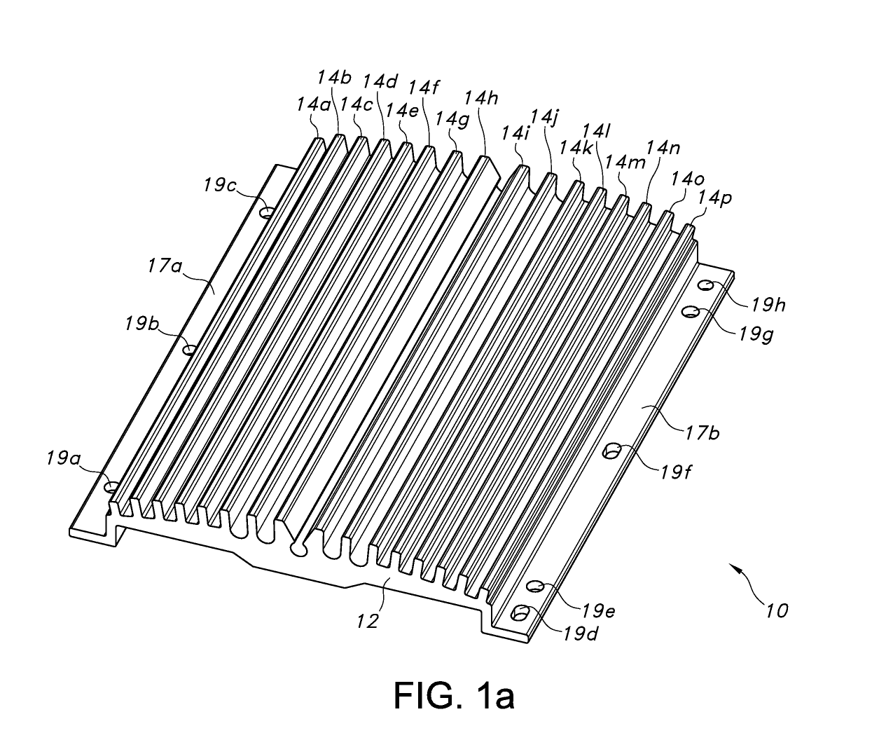

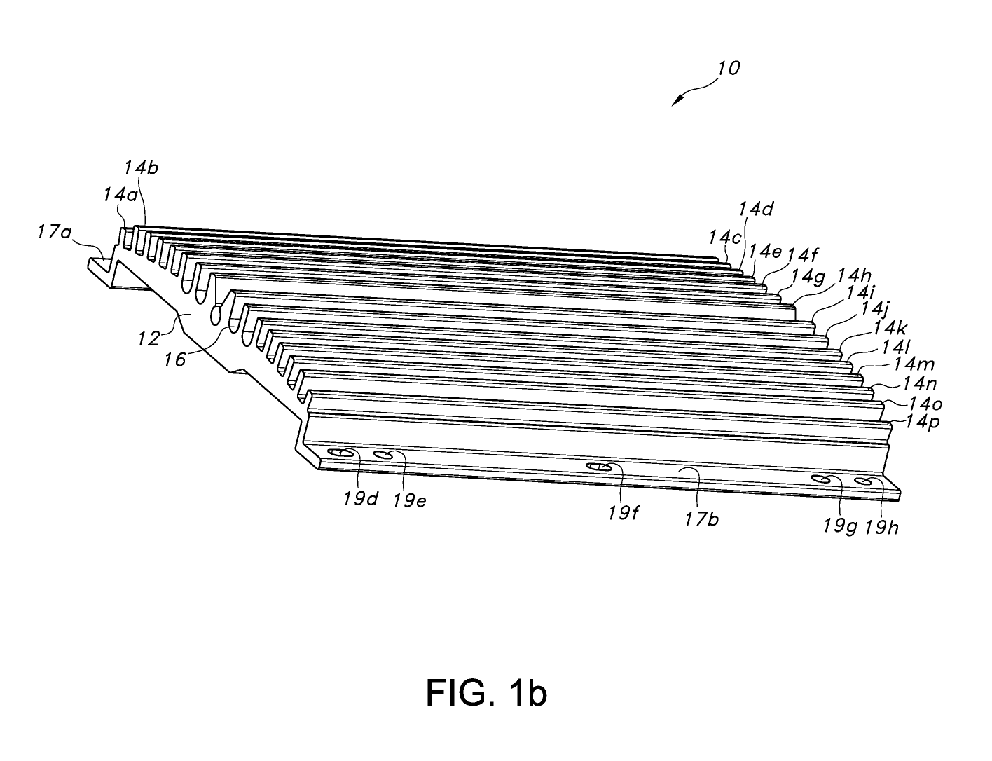

FIG. 1a-b are perspective views of one embodiment of a heat sink 10 of the present invention, including a rectangular base 12 and sixteen rectangular fins 14a-p extending from an upper convex surface 16 of base 12. Fins 14a-g and 14j-p may be substantially planar. Heat sink 10 may include two elongate flanges 17a-b on opposite sides thereof. Flanges 17a-b may include throughholes, such as throughholes 19a-h, through which heat sink 10 may be secured to a heat generating electronic component. Heat sink 10 may be formed of extruded aluminum, or some other material that is a good conductor of heat.

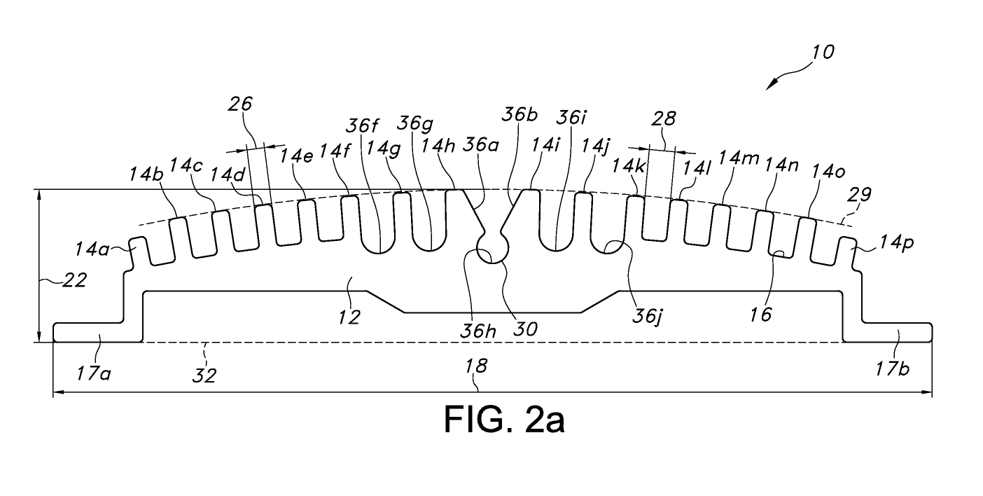

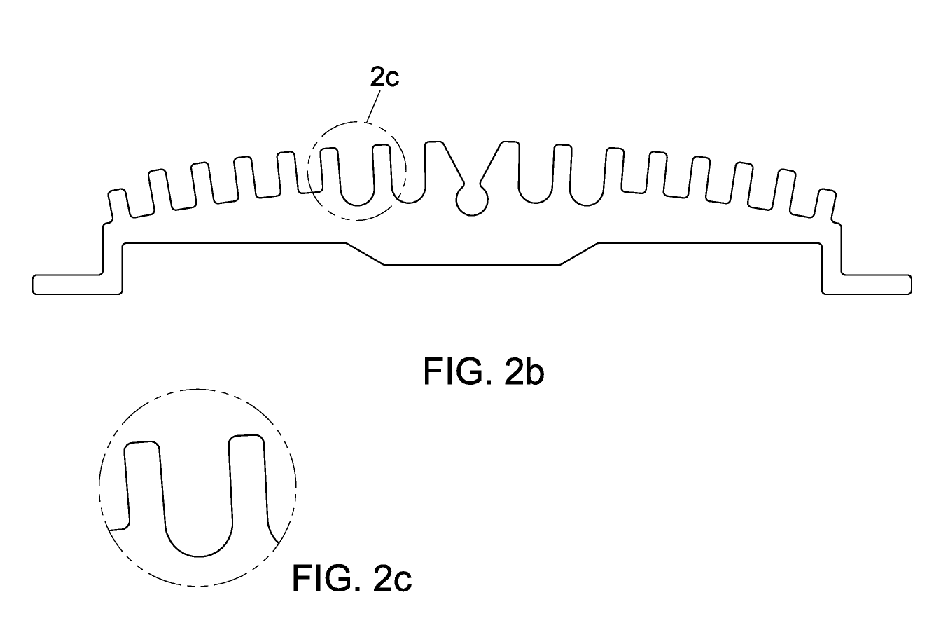

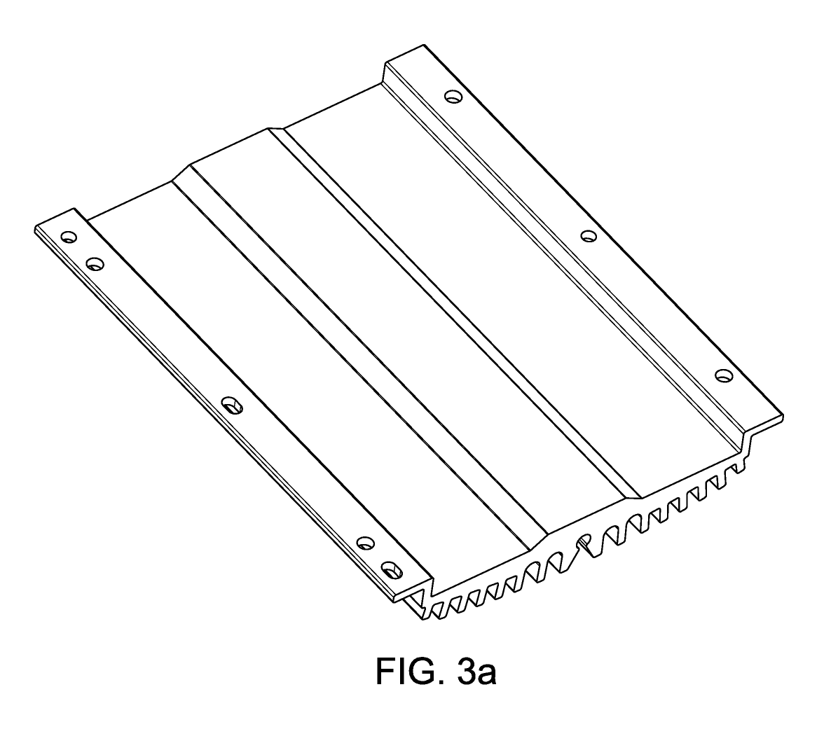

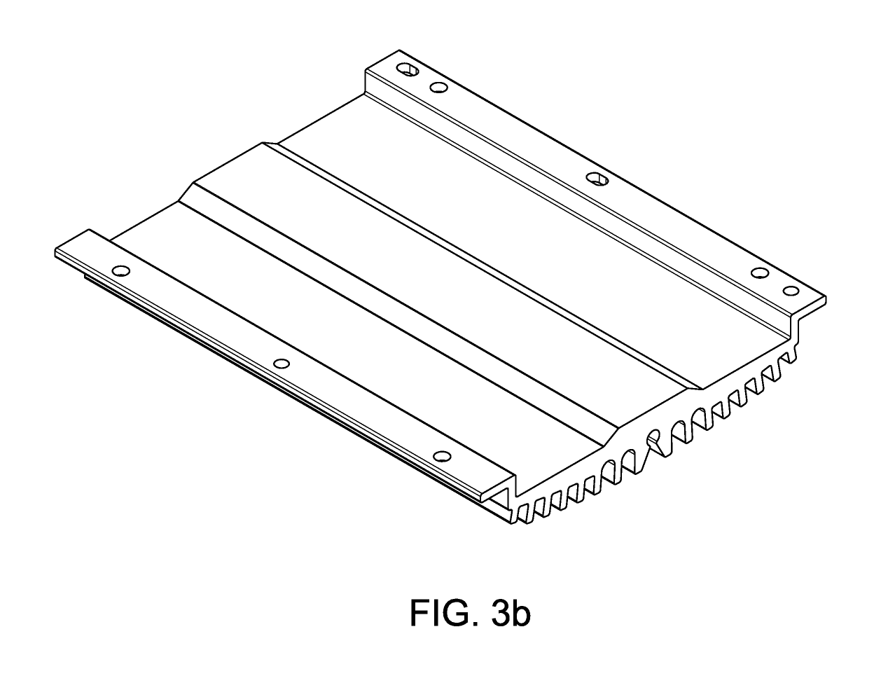

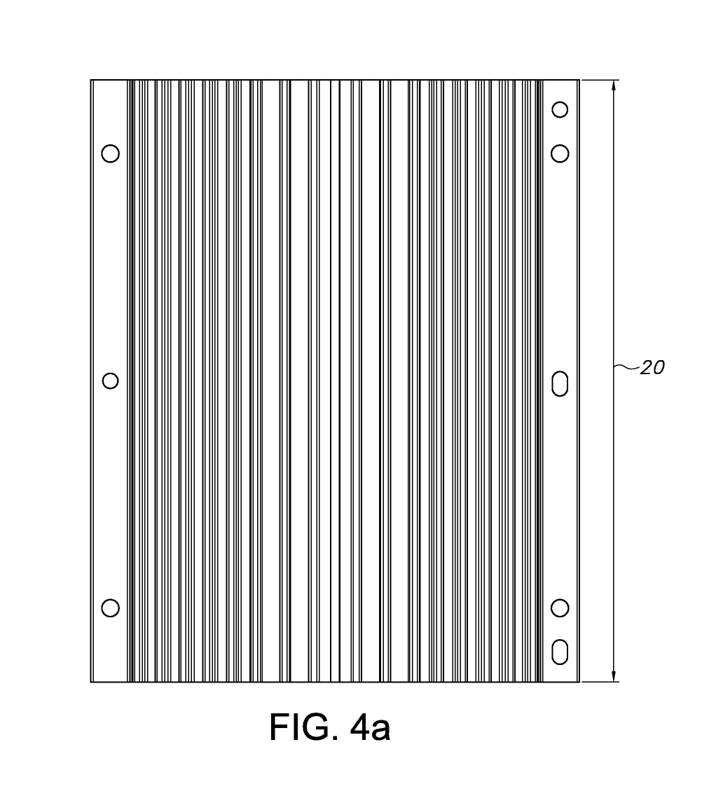

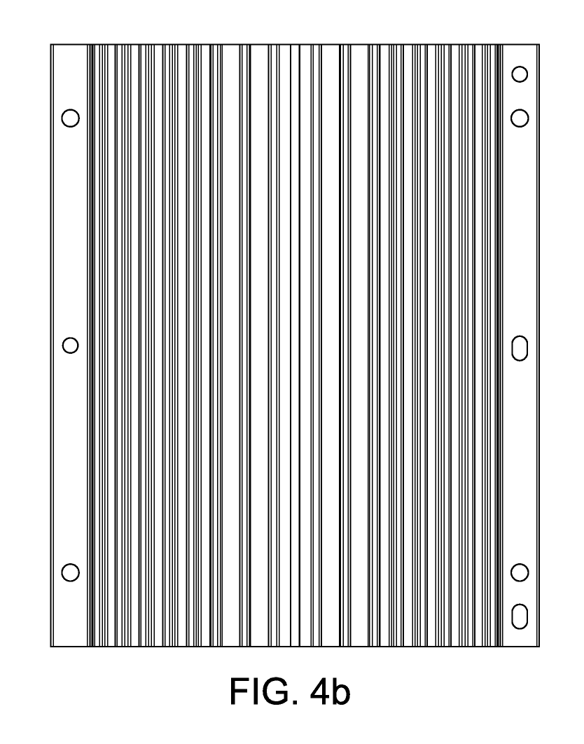

Base 12 may have a width 18 (FIG. 2a) of approximately between 80 and 100 millimeters, a length 20 (FIG. 4a) of approximately between 110 and 135 millimeters. A height 22 of heat sink 10 may be approximately between 12 and 25 millimeters. Each of fins 14a-g and 14j-p may have a thickness 26 of approximately between 1.5 and 2.5 millimeters. A distance 28 between each pair of adjacent fins 14 may be approximately between 1.0 and 4.0 millimeters at the proximal ends of each fin 14, i.e., at upper surface 16. The upper or distal edges of fins 14b-o may define a substantially continuous and convex envelope 29.

As best illustrated in FIG. 2a, base 12 has a tapered cross section across its width, thus providing a convex fin mounting surface 16. The thickest portion of base 12 is in the center where a lower surface 30 is lowest. Lower surface 30 ramps upward and base 12 becomes thinner farther away from the center, providing the highest thermal conduction at the heat source. This configuration may reduce spreading resistance, and provide clearance for connector pins and the mounting of devices on a printed circuit board 32.

Fins 14a-p may be fanned out from each other. More particularly, fin gaps 28 may increase towards the upper ends of the fins, resulting in improved convective air flow away from fins 14a-p.

The spacing between the two innermost or middle fins 14h-i may be larger than the spacing 28 between other fins 14 to provide greater convective air flow at the heat source and increased heat dissipation. Middle fins 14h-i may have angled inner surfaces 34a-b which provide an increasing gap between fins 14h-i toward the distal ends of tins 14h-i, and which thereby promotes more convective air flow at the center of the heat source.

Fins 14f-k, which may be located directly above the heat source, may have channels 36f-j of partially circular cross section between adjacent ones of the fins. The channels 36f-j of partially circular cross section may receive attachment screws from the sides, e.g., in directions into or out of the page of FIG. 2a. In contrast, fins 14a-f and 14k-p may have flat surfaces between adjacent ones of the fins. Channels 36f-g and 36i-j are concave and semi-circular, and provide about 50-60% more surface area than do flat surfaces. Channel 36h forms about 315 degrees of a circle.

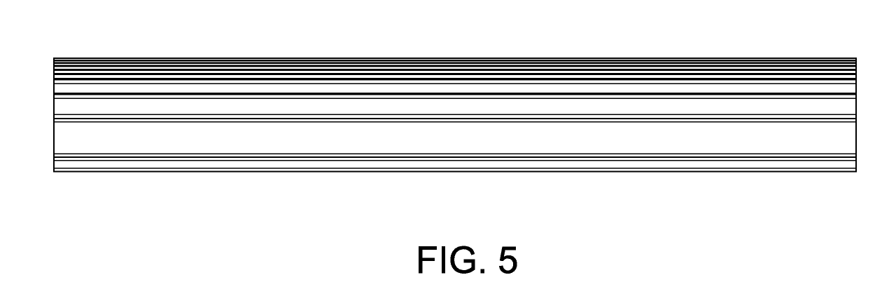

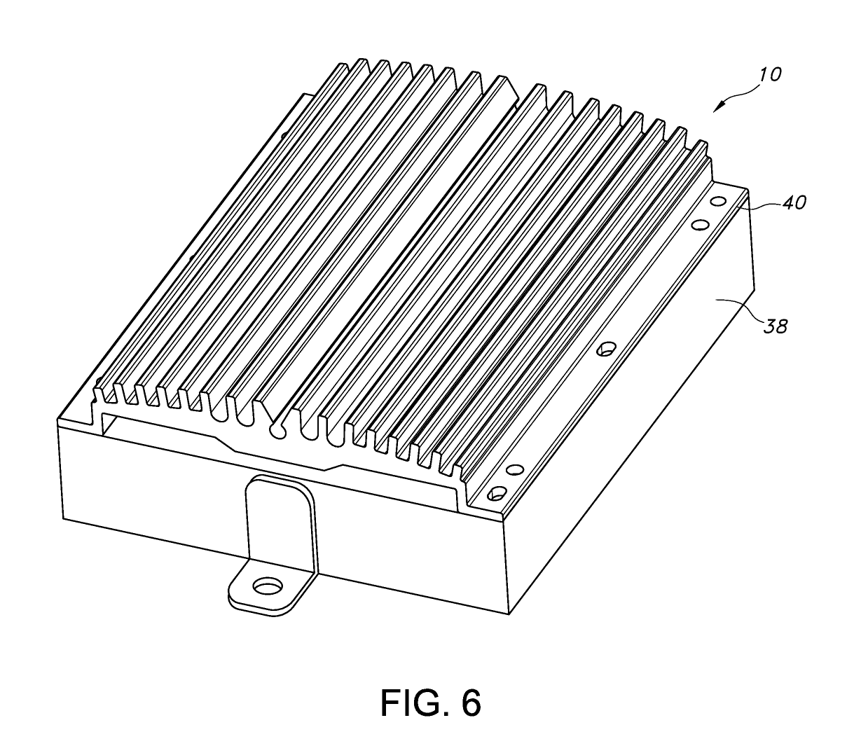

A specific embodiment of a heat sink of the present invention is shown in FIGS. 2b, 4b and 5 with specific dimensions.

FIG. 6 is a top perspective view of heat sink 10 attached to a heat generating electronic component 38. A heat spreader pad (not shown) may be disposed at 40 between heat sink 10 and electronic component 38.

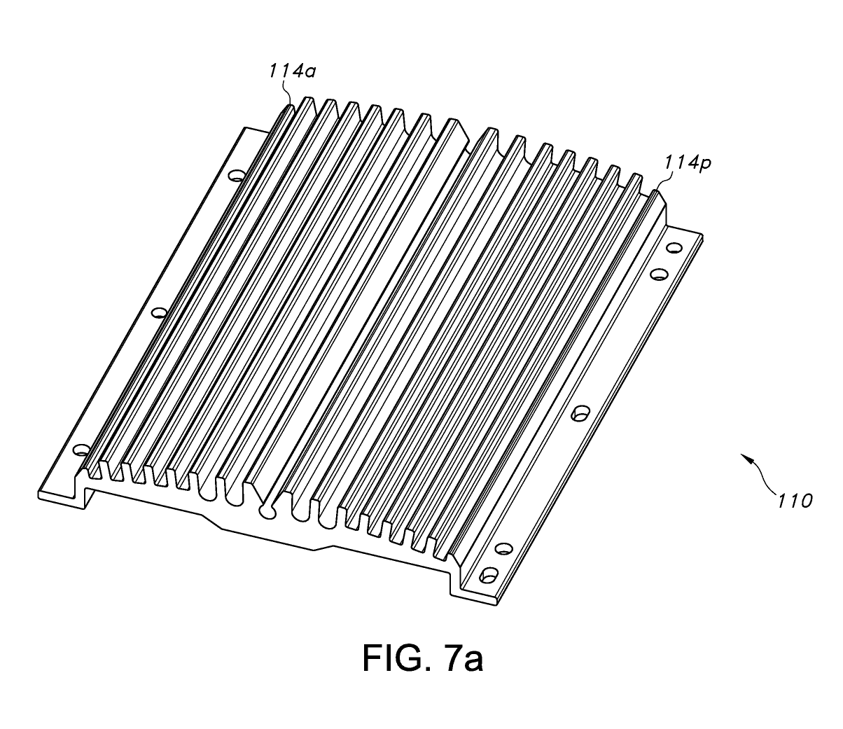

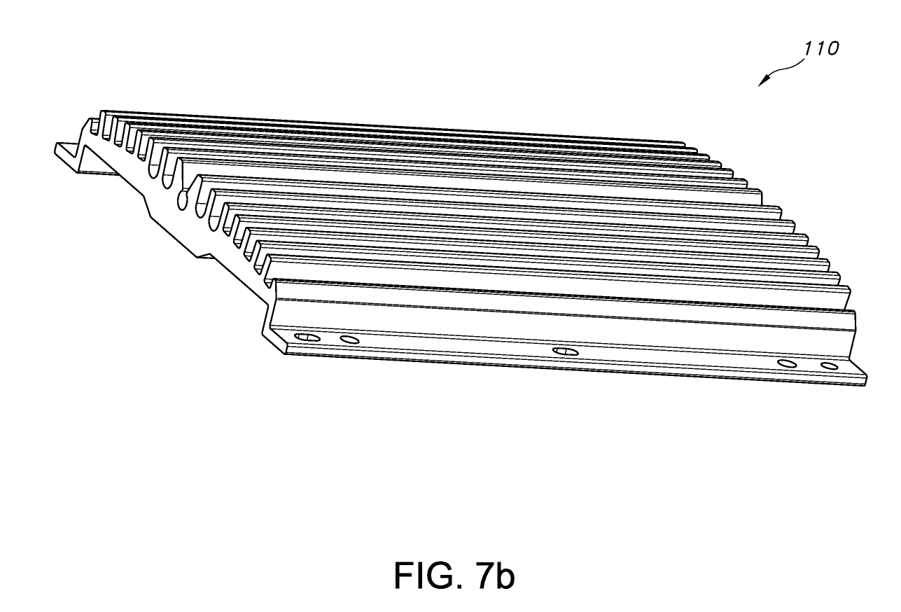

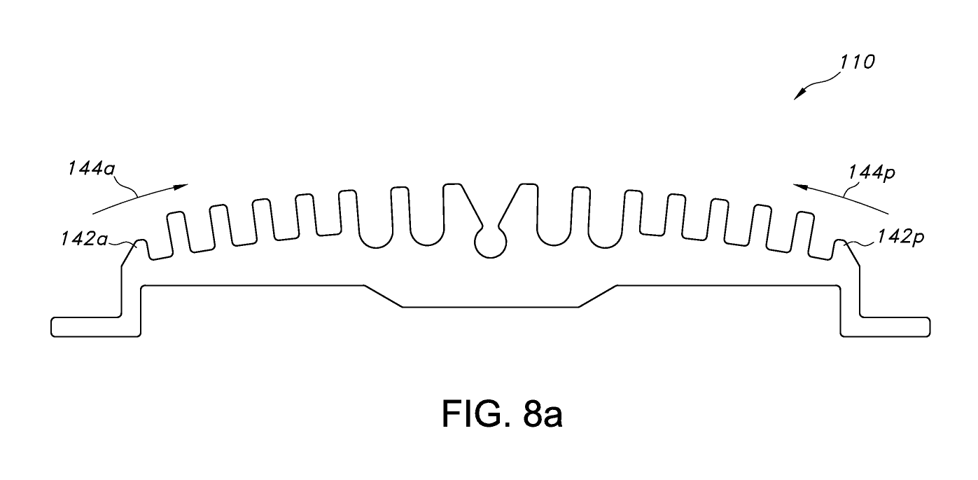

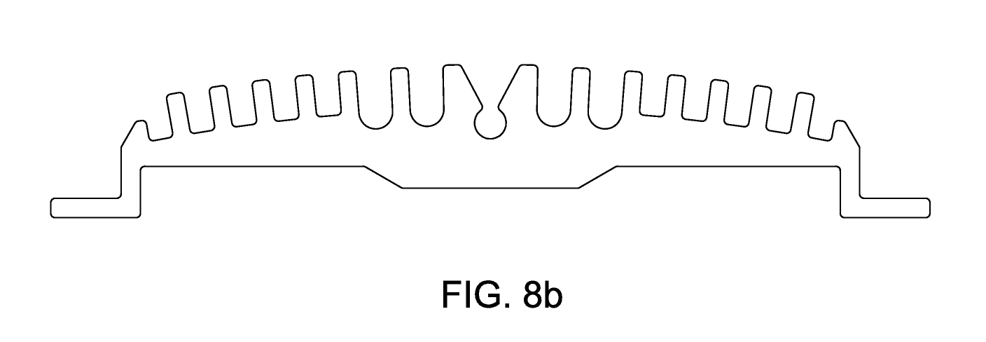

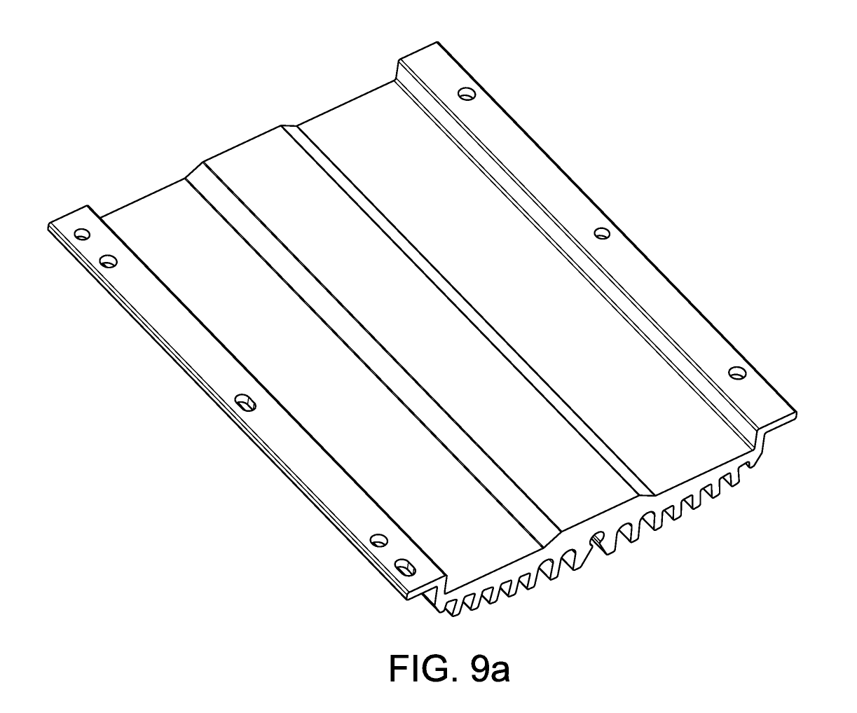

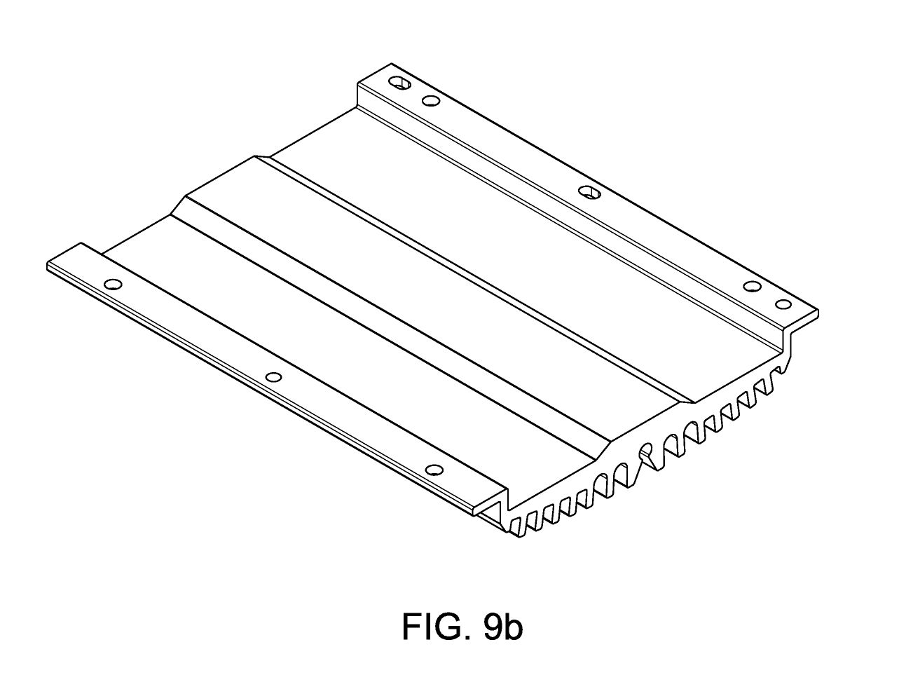

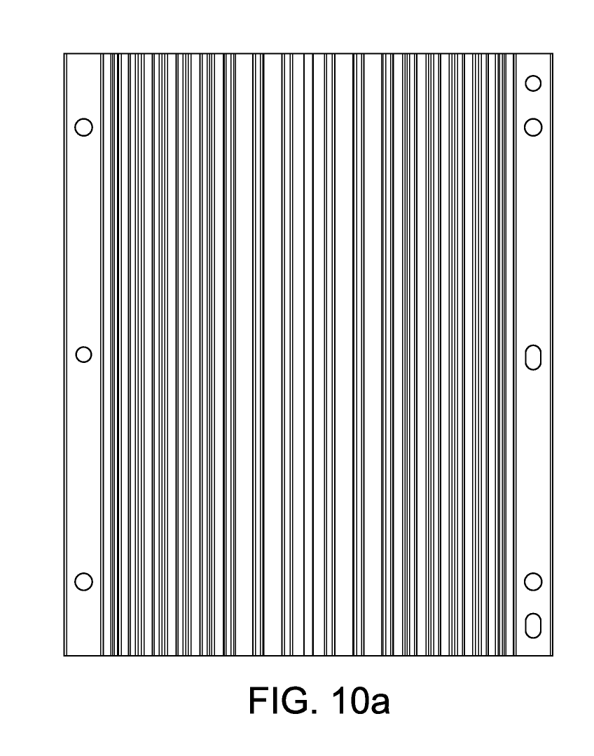

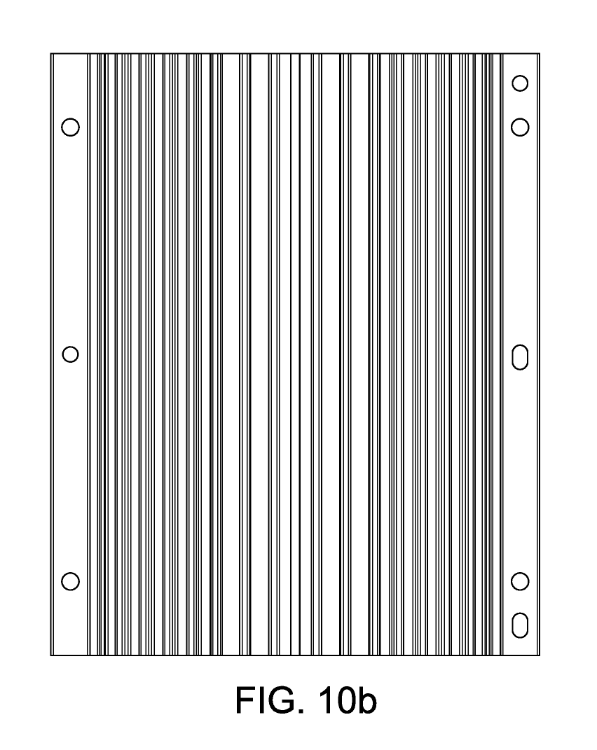

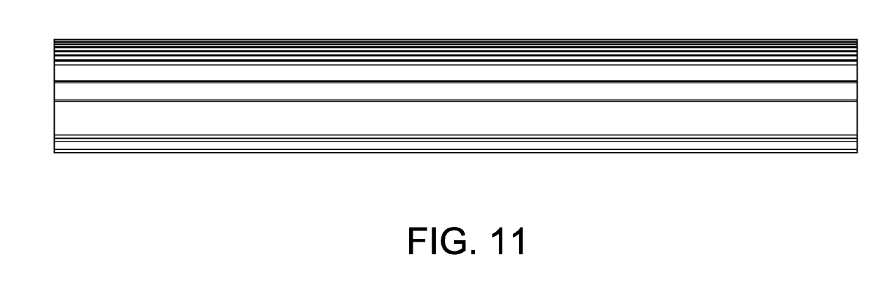

Another embodiment of a heat sink 110 of the present invention is shown in FIGS. 7-11. Heat sink 110 differs from heat sink 10 in that fins 114a and 114p are shorter than fins 14a and 14p and have respective chamfered outer corners 142a and 142p (FIG. 8a). Thus, fins 114a and 114p enable improved air flow across heat sink 110 at directions indicated by arrows 144a and 144p, which are generally at right angles to the fins.

While this invention has been described as having an exemplary design, the present invention may be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains.

What is claimed is:

1. A heat sink for an electronic component, comprising:
a base having a width, the base having a greater thickness at a middle portion along the width than at opposite end portions along the width; and
a plurality of elongate fins projecting from a surface of the base and extending in directions perpendicular to the surface.

2. The heat sink of claim 1 wherein the surface of the base is convexly shaped.

3. The heat sink of claim 1 wherein the surface of the base includes a plurality of concavely shaped channels, each said channel being disposed between a respective adjacent pair of the fins.

4. The heat sink of claim 3 wherein the channels have semi-circular-shaped cross sections.

5. The heat sink of claim 1 wherein end ones of the fins are shorter than all other ones of the fins.

6. The heat sink of claim 5 wherein two opposite end ones of the fins have substantially equal heights which are at most one-half heights of all other ones of the fins.

7. The heat sink of claim 6 wherein the two opposite end ones of the fins have chamfered outer distal corners.

8. The heat sink of claim 1 wherein two middle ones of the fins have angled planar inner surfaces such that the two middle fins are thicker at proximal ends of the middle fins than at distal ends of the middle fins.

9. The heat sink of claim 1 wherein end ones of the fins are thinner than middle ones of the fins.

10. The heat sink of claim 1 wherein distal ends of the fins define a substantially continuous and convex envelope.

11. A heat sink for an electronic component, comprising;
a base having a convexly shaped surface; and
a plurality of elongate fins projecting from the surface of the base and extending in directions perpendicular to the surface.

12. The heat sink of claim 11 wherein the base has a width, the base having a greater thickness at a middle portion along the width than at opposite end portions along the width.

13. The heat sink of claim 11 wherein the surface of the base includes a plurality of concavely shaped channels, each said channel being disposed between a respective adjacent pair of the fins, the channels having semi-circular-shaped cross sections.

14. The heat sink of claim 11 wherein two opposite end ones of the fins have substantially equal heights which are at most one-half heights of all other ones of the fins, the two opposite end ones of the fins having chamfered outer distal corners.

15. The heat sink of claim 11 wherein two middle ones of the fins have angled planar inner surfaces such that the two middle fins are thicker at proximal ends of the middle fins than at distal ends of the middle fins.

16. The heat sink of claim 11 wherein end ones of the fins are thinner than middle ones of the fins.

17. The heat sink of claim 11 wherein distal ends of the fins define a substantially continuous and convex envelope.

18. A heat sink for an electronic component, comprising:
a base including a surface and having a plurality of substantially parallel channels disposed in the surface; and
a plurality of elongate fins projecting from the surface of the base and extending in directions perpendicular to the surface and parallel to the channels, each said fin being disposed between two adjacent said channels.

19. The heat sink of claim 18 wherein the channels have semi-circular-shaped cross sections.

20. The heat sink of claim 18 wherein one of the channels has a cross section that forms a continuous are of at least 210 degrees.
